(19) United States
(12) Patent Application Publication
(10) Pub. No.: US 2015/0216071 A1
(43) Pub. Date: Jul. 30, 2015

(54) SLIDING RAIL MECHANISM AND RACK WITH SLIDING RAIL MECHANISM

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventors: CHEN-LU FAN, New Taipei (TW); CHANG-GUI CHEN, Shenzhen (CN)

(21) Appl. No.: 14/524,931

(22) Filed: Oct. 27, 2014

(30) Foreign Application Priority Data
Jan. 25, 2014 (CN) 201410034571.7

(51) Int. Cl. H05K 7/14

(52) U.S. Cl. CPC H05K 7/1489

(57) ABSTRACT

A sliding rail mechanism includes a first rail, a second rail slidably mounted to the first rail, a third rail slidably mounted to the second rail, and a securing member. The securing member includes a stopping portion and an engaging portion. The second rail and the third rail can slide in a first direction. The stopping portion and the engaging portion are insertable into the second rail when the second rail slides to a first position. The stopping portion can prevent the second rail from sliding in the first direction. The engaging portion can prevent the middle rail from sliding in a second direction opposite to the first direction. The engaging portion is extruded out from the second rail when the inner rail is slided to a second position, thereby enabling the second rail to slide in the second direction. A rack with the sliding rail mechanism is also provided.

### CROSS-REFERENCE TO RELATED APPLICATIONS

This application claims priority to Chinese Patent Application No. 201410034571.7 filed on January 25, 2014, the contents of which are incorporated by reference herein.

### FIELD

The subject matter herein generally relates to a rack with a sliding rail mechanism for severs.

### BACKGROUND

A rack with a sliding rail mechanism is used to hold a plurality of severs.

### BRIEF DESCRIPTION OF THE DRAWINGS

Implementations of the present technology will now be described, by way of example only, with reference to the attached figures.

FIG. 1 is an assembled, isometric view of an embodiment of a rack with sliding rail mechanism.

FIG. 2 is an exploded, isometric view of an embodiment of the rack with sliding rail mechanism, but two brackets are not shown.

FIG. 3 is an isometric view of a securing member of the rack with sliding rail mechanism of the FIG. 2.

FIG. 4 is an exploded, isometric view of a first rail, a second rail, and a third rail of the rack with sliding rail mechanism of the FIG. 2.

FIG. 5 is an assembled, isometric view of a sliding rail mechanism of the rack with sliding rail mechanism of FIG. 2, and the second rail is in a first position.

FIG. 6 is similar to FIG. 5, but the second rail is in a second position.

FIG. 7 is an isometric, cutaway view of the sliding rail mechanism of FIG. 5.

FIG. 8 is similar to FIG. 7, but viewed in a different aspect.

FIG. 9 is an assembled, isometric view of the rack with sliding rail mechanism of FIG. 2, and two brackets are not shown.

FIG. 10 is an enlarged view of a circled portion X of FIG. 9.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other feature that the term modifies, such that the component need not be exact. For example, substantially cylindrical means that the object resembles a cylinder, but can have one or more deviations from a true cylinder. The term “comprising,” when utilized, means “comprising, but not necessarily limited to”; it specifically indicates open-ended inclusion or membership in the so-described combination, group, series and the like.

The present disclosure is in relation to a rack with a sliding rail mechanism for receiving severs.

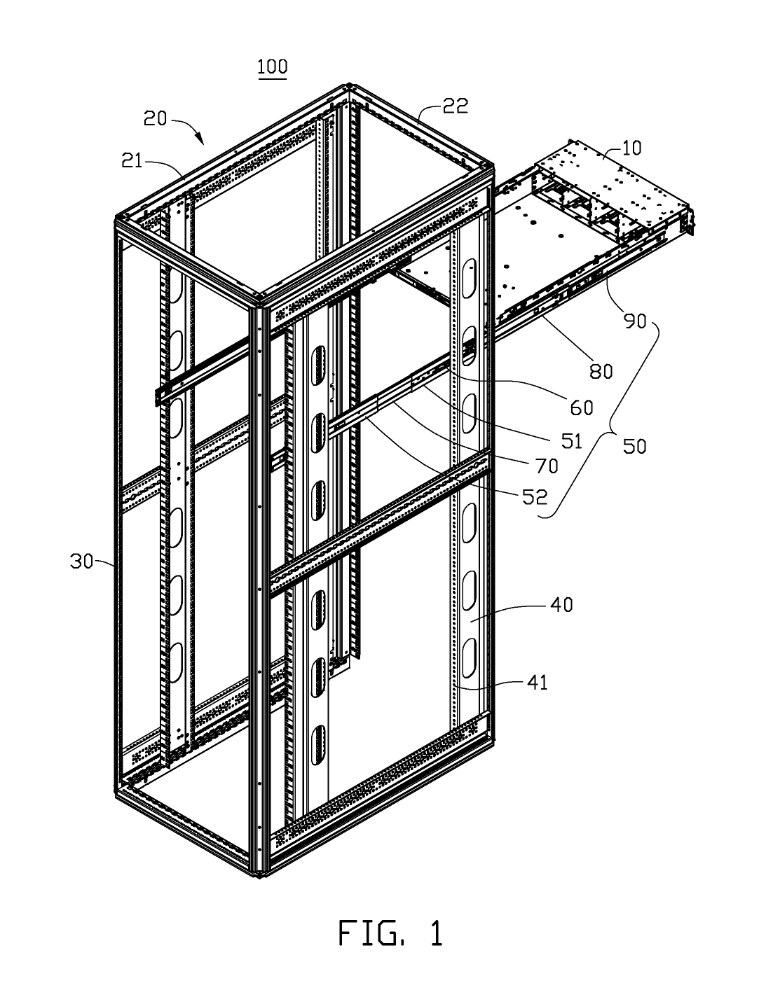

FIG. 1 illustrates an embodiment of a rack with sliding rail mechanism 100 for receiving a plurality of drawers 10. The rack 100 comprises two brackets 20, four posts 30, four mounting plates 40, and a plurality of sliding rail mechanisms 50.

Each bracket 20 comprises two first poles 21 substantially parallel to each other and two second poles 22 substantially perpendicular to the first poles 21. Each post 30 is connected between the two brackets 20. A cubiform is cooperatively defined by the two brackets 20 and the four posts 30. Two ends of each mounting plate 40 are connected to the first poles 21. The mounting plates 40 define a plurality of mounting holes 41.

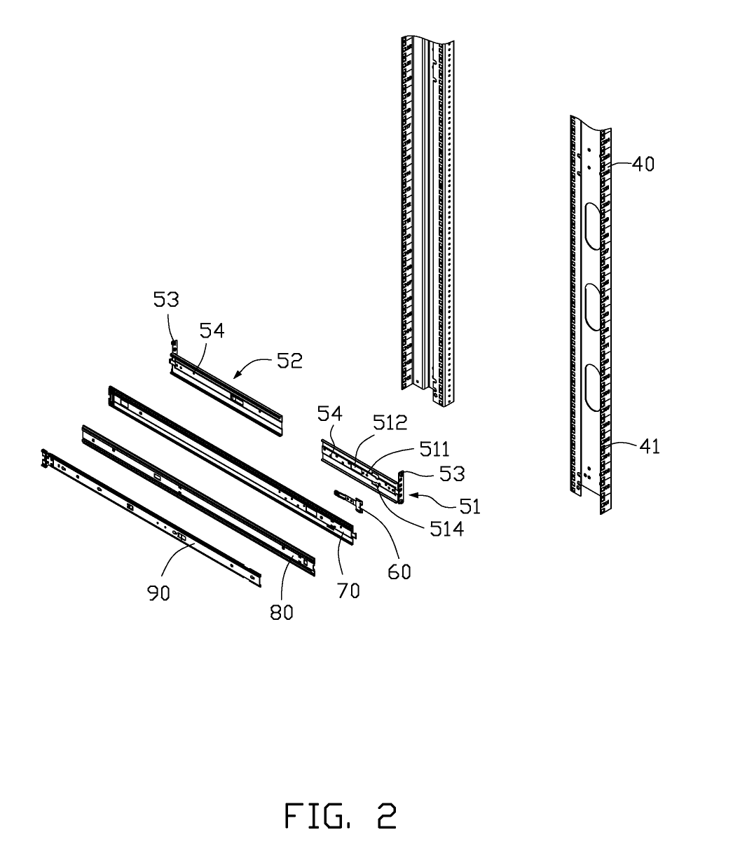

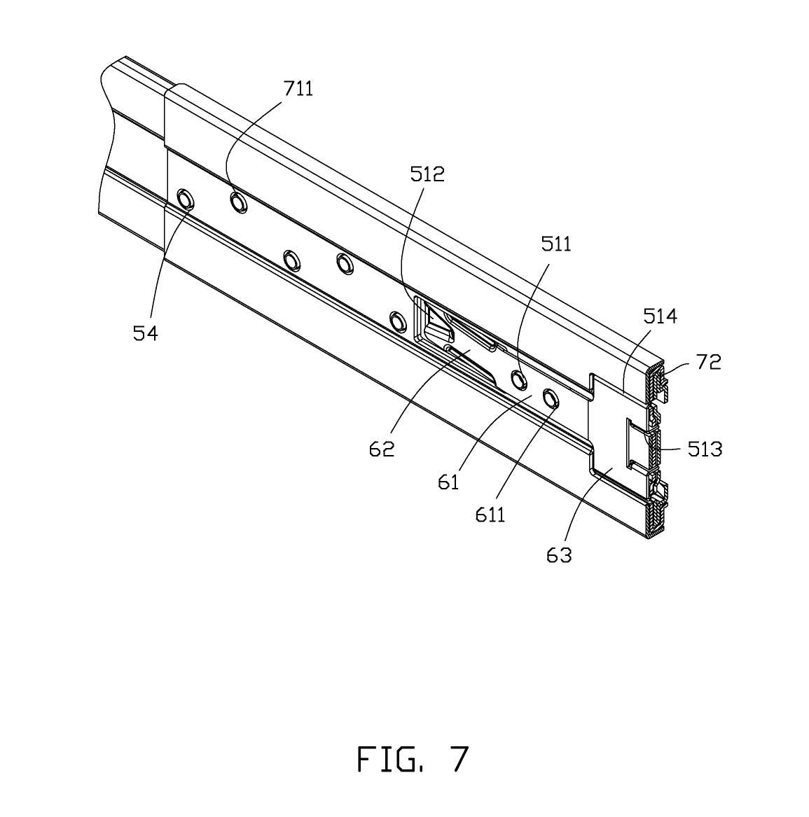

FIG. 2 illustrates that each sliding rail mechanism 50 comprises a first securing plate 51, a second securing plate 53, a securing member 60, a first sliding rail 70, a second sliding rail 80, and a third sliding rail 90. Each securing plate 51 and the second securing plate 53 comprise two positioning members 53 and define a plurality of connecting holes 54. The first securing plate 51 further comprises a protrusion 511 and defines a stopping hole 512, two securing holes 513 (shown in FIG. 7), and two receiving holes 514.

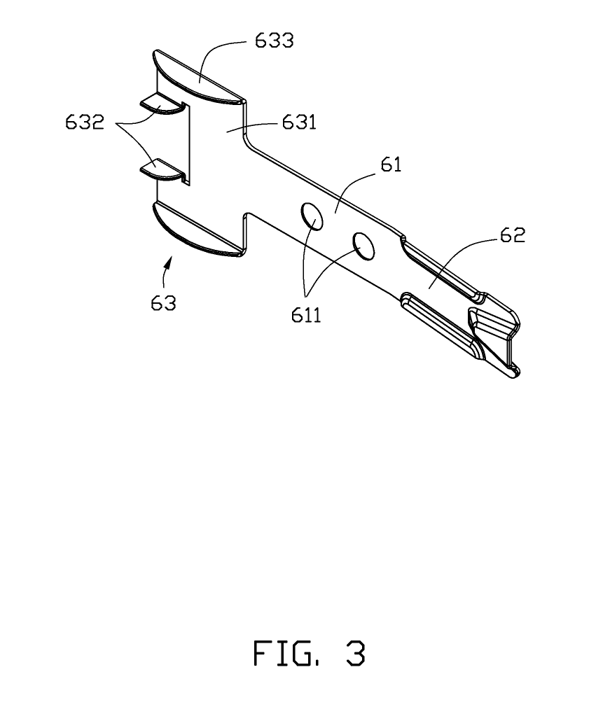

FIG. 3 illustrates that the securing member 60 (shown in FIG. 2) comprises a connecting portion 61, a stopping portion 62, and an engaging portion 63. The stopping portion 62 and the engaging portion 63 are coupled to two different ends of the connecting portion 61. The connecting portion 61 defines two fastening holes 611. The engaging portion 65 comprises an engaging plate 631, two engaging tabs 632 substantially parallel to each other and substantially perpendicular to the engaging plate 631, and two positioning pieces 633 substantially parallel to each other and substantially perpendicular to the engaging plate 631.

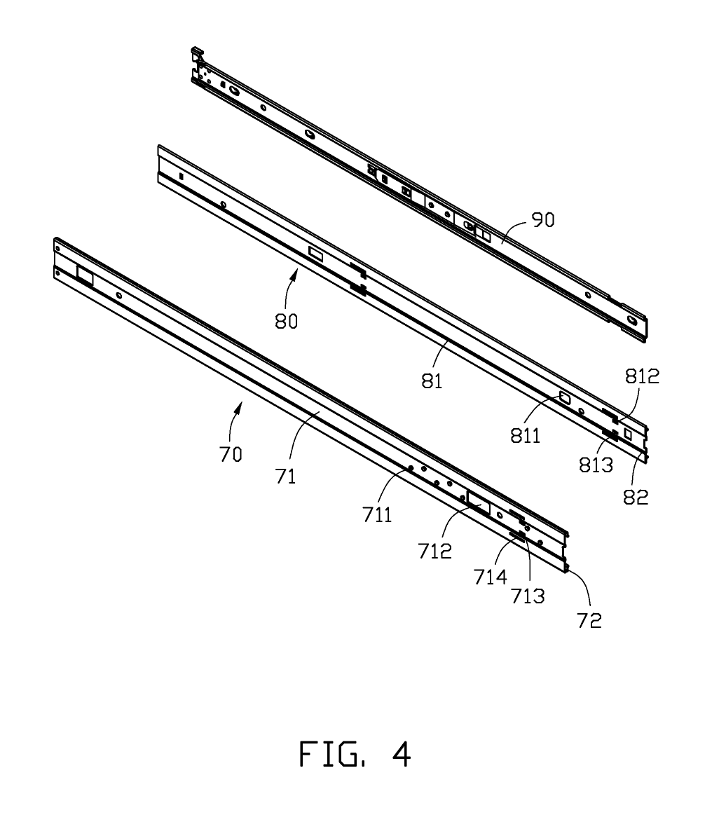

FIG. 4 illustrates that the first rail 70 comprises a first sidewall 71 and two first positioning portions 72. The first sidewall 71 defines a plurality of mounting blocks 711 corresponding to the connecting holes 54, a first through hole 712, two first engaging holes 713, and two first positioning holes 714. The second rail 80 is configured to be received in the first positioning portions 72.

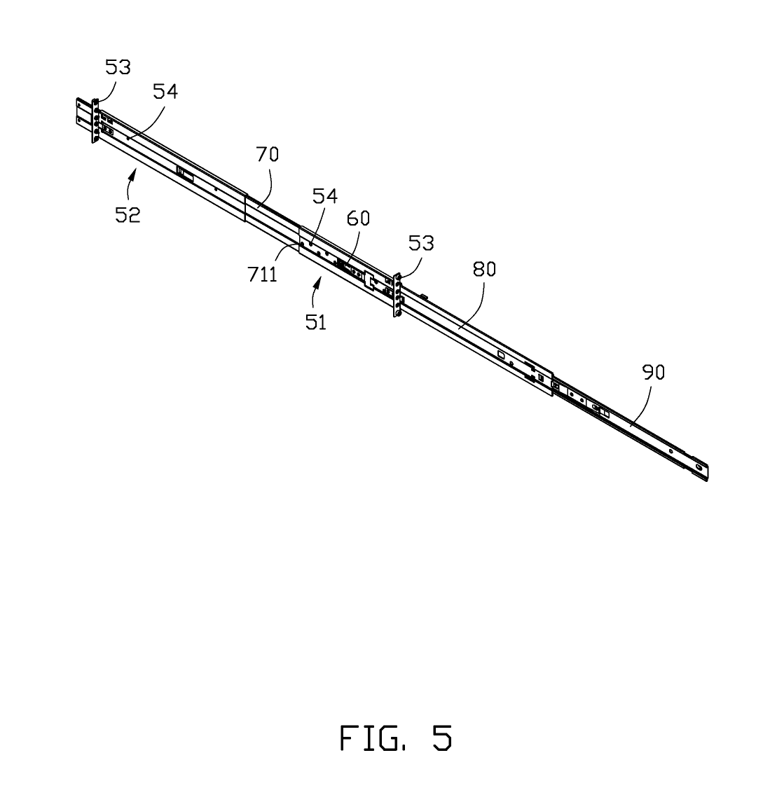

FIG. 5 illustrates that the third rail 80 comprises a second sidewall 81 and two second positioning portions 82. The second sidewall 81 defines a plurality of mounting blocks 811, two second engaging holes 812, and two second positioning holes 813. The third rail 90 is configured to be received in the second positioning portions 82.

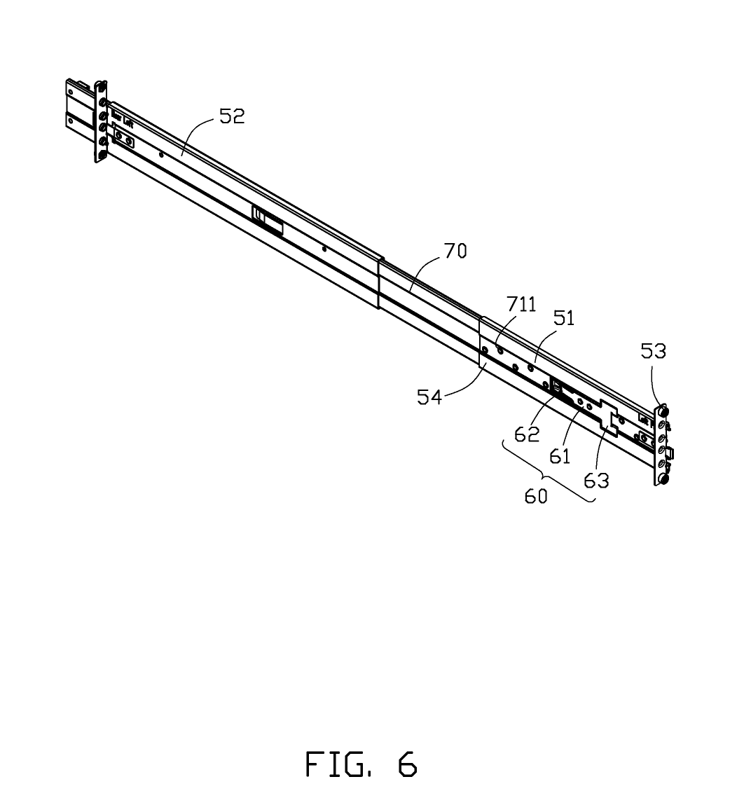

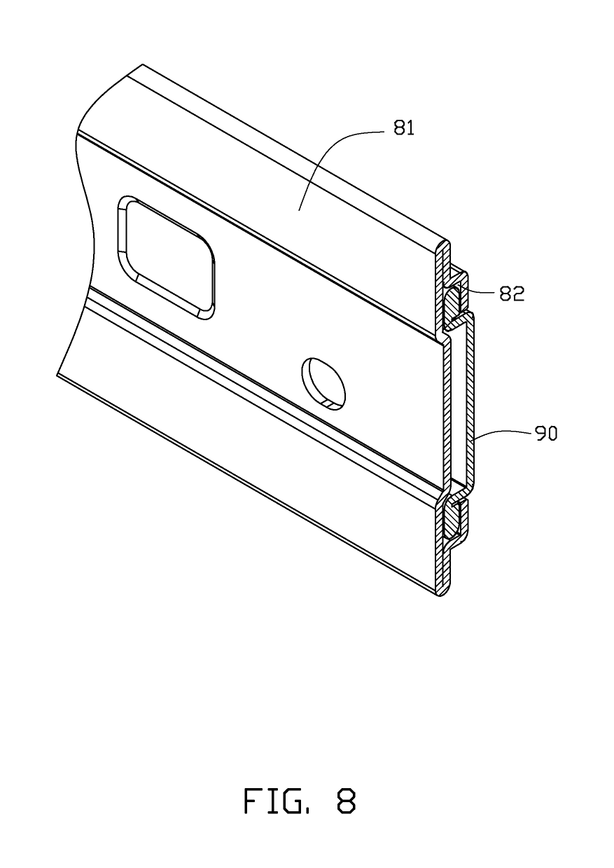

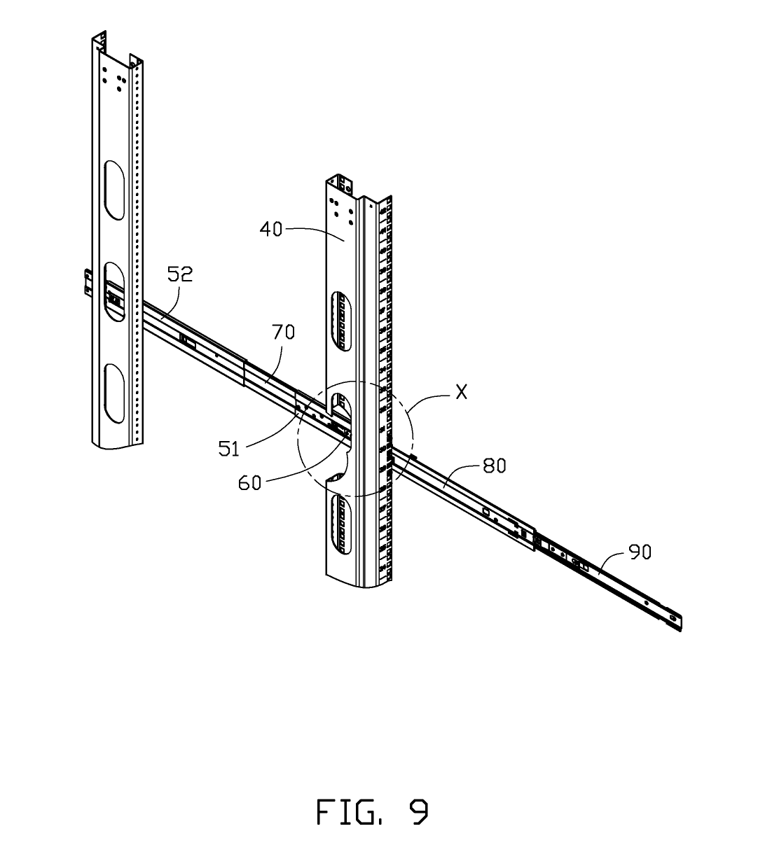

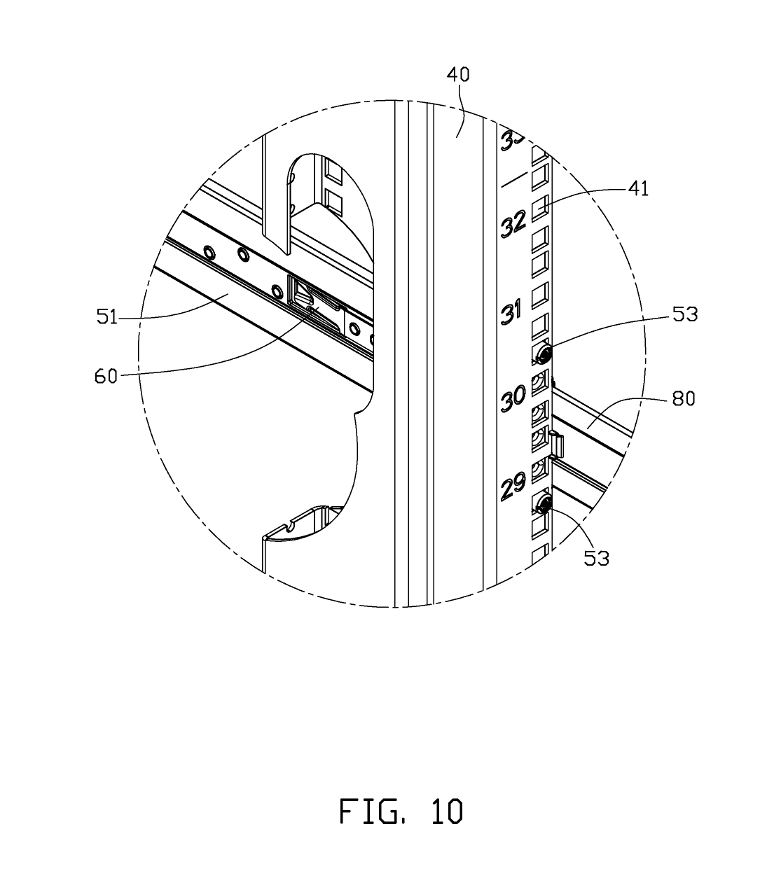

FIGS. 4-10 illustrate that in assembly, the third rail 90 is slidably mounted to the second positioning portion 82. The second sidewall 81 is slidably mounted to the first positioning portion 72. The mounting blocks 711 are inserted into the corresponding connecting holes 54. The first rail 70 is secured to the first securing plate 51 and the second securing plate 52. The stopping hole 512 is aligned with the first through hole 712. The protrusions 511 are inserted into the fastening holes 611. The securing member 60 is secured to the first securing plate 51. The stopping portion 62 is received in the stopping hole 512 and the first through hole 712. The stopping portion 62 abuts on the second sidewall 81. The engaging tabs 632 (shown in FIG. 3) are received in the corresponding stopping holes 512 and the corresponding first through holes 712. The engaging tabs 632 abut on the second sidewall 81. The positioning tabs 633 (shown in FIG. 3) are received in the corresponding receiving holes 514 and the corresponding first positioning holes 712. The positioning tabs 633 (shown in FIG. 3) abut against the second sidewall 81.

FIGS. 1 and 9-10 illustrate that the positioning members 53 of the first securing plate 51 and the second securing plate 52 are inserted into the corresponding mounting holes 41. The drawer 10 is mounted to two third rails 90 and mounted on the rack 100.

FIGS. 4-5 and 7-8 illustrate when in use, the drawer 10 is pulled out from the rack 100 in a first direction away from the bracket 20. The third rail 90 slides in the first direction away from the bracket 20. The second rail 80 slides in the first direction to a first position. The stopping portion 62 is received in the second through hole 811. The engaging tabs 632 are engaged in the corresponding second engaging holes 812. The positioning pieces 633 are inserted into the corresponding positioning holes 813. Thus, the second rail 80 is located in first position. The stopping portion 62 prevents the second rail 80 from sliding in a second direction opposite to the first direction. The positioning pieces 633 extend through the second positioning holes 813.

FIGS. 1, and 3-4 illustrate when not use, the drawer 10 is pushed toward the bracket 20 in the second direction. The third rail 90 slides in the second direction until the positioning pieces 633 are elastically deformed to enable the engaging tabs 632 to disengage from the second engaging holes 812. The second rail 80 is pushed in the second direction. The stopping portion 62 is elastically deformed to disengage from the second through hole 811. The second rail 80 slides to a second position. The drawer 10 is received in the rack 100.

It is to be understood that even though numerous characteristics and advantages have been set forth in the foregoing description of embodiments, together with details of the structures and functions of the embodiments, the disclosure is illustrative only and changes may be made in the details, especially in the matters of shape, size, and arrangement of parts within the principles of the disclosure to the full extent indicated by the broad general meaning of the terms in which the appended claims are expressed.

What is claimed is:

1. A sliding rail mechanism in a rack, the sliding rail mechanism comprising:
a first rail;
a second rail slidably mounted to the first rail;
a third rail slidably mounted to the second rail; and
a securing member having a stopping portion and an engaging portion,
wherein, the second rail and the third rail can slide in a first direction,
the stopping portion and the engaging portion are insertable in the second rail when the second rail is in a first position,
the stopping portion prevents the second rail from sliding in the first direction and the engaging portion prevents the middle rail from sliding in a second direction opposite to the first direction, and
the engaging portion is extruded out from the second rail when the inner rail is slide to a second position, thereby enabling the second rail to slide in the second direction.

2. The sliding rail mechanism of claim 1, further comprises a first securing plate and a second securing plate, wherein the first securing plate and the second securing plate are mounted to two ends of the first rail and are configured to secure the sliding rail mechanism to a rack.

3. The sliding rail mechanism of claim 2, wherein the securing member defines a fastening hole, the first securing plate comprises a protrusion secured in the fastening hole.

4. The sliding rail mechanism of claim 2, wherein the first securing plate defines a stopping hole receiving the stopping portion.

5. The sliding rail mechanism of claim 4, wherein the first rail defines a first through hole, the stopping portion can extend through the stopping hole to be received in the first through hole.

6. The sliding rail mechanism of claim 5, wherein the second rail defines a second through hole, the stopping portion can be received in the first through hole and the second through hole.

7. The sliding rail mechanism of claim 4, wherein the engaging portion comprises an engaging tab and a positioning piece, the first securing plate further defines a securing hole receiving the engaging tab and a receiving hole receiving the positioning piece.

8. The sliding rail mechanism of claim 7, wherein the first rail defines a first engaging hole receiving the engaging tab and a first positioning hole receiving the positioning piece.

9. The sliding rail mechanism of claim 8, wherein the second rail defines a second engaging hole and a second positioning hole, the engaging tab can be received in the first engaging hole and the second engaging hole, and the positioning piece can be received in the first positioning portion and the second positioning hole.

10. The sliding rail mechanism of claim 1, wherein the first rail comprises a first positioning portion receiving the second rail and the second rail comprises a second positioning portion receiving the third rail.

11. A rack with sliding rail mechanism, the sliding rail mechanism comprising:
a sliding rail mechanism configured to mounted to a drawer and comprising:
a first rail;
a second rail slidably mounted to the first rail;
a third rail slidably mounted to the second rail; and
a securing member comprising:
a connecting portion;
a stopping portion coupled to a first end of the connecting portion; and
an engaging portion coupled to a second end of the connecting portion,
wherein, the second rail and the third rail can slide in a first direction;
the stopping portion and the engaging portion are insertable into the second rail when the second rail slide to a first position;
the stopping portion prevents the second rail from sliding in the first direction and the engaging portion prevents the middle rail from sliding in a second direction opposite to the first direction; and
the engaging portion is extruded out from the second rail when the inner rail is slided to a second position, thereby enabling the second rail to slide in the second direction.

12. The rack of claim 11, further comprises a first securing plate, wherein the first securing plate is mounted to one end of the first rail and is configured to secure the sliding rail mechanism to the rack, the connecting portion is mounted to the first securing plate.

13. The rack of claim 12, wherein the securing member defines a fastening hole, the connecting portion comprises a protrusion secured in the fastening hole.

14. The rack of claim 12, wherein the first securing plate defines a stopping hole receiving the stopping portion.

15. The rack of claim 14, wherein the first rail defines a first through hole, the stopping portion can extend through the stopping hole to be received in the first through hole.

16. The rack of claim 15, wherein the second rail defines a second through hole, the stopping portion can be received in the first through hole and the second through hole.

17. The rack of claim 14, wherein the engaging portion comprises an engaging tab and a positioning piece, the first securing plate further defines a securing hole receiving the engaging tab and a receiving hole receiving the positioning piece.

18. The rack of claim 17, wherein the first rail defines a first engaging hole receiving the engaging tab and a first positioning hole receiving the positioning piece.

19. The rack of claim 18, wherein the second rail defines a second engaging hole and a second positioning hole, the engaging tab can be received in the first engaging hole and the second engaging hole, and the positioning piece can be received in the first positioning portion and the second positioning hole.

20. The rack of claim 12, further comprises two mounting plates, wherein the first securing plate is mounted to the two mounting plates.
